(19) United States
(12) Patent Application Publication
(10) Pub. No.: US 2022/0180925 A1
(43) Pub. Date: Jun. 9, 2022

(54) SELECTOR DEVICE, RESISTIVE TYPE MEMORY DEVICE AND ASSOCIATED MANUFACTURING METHOD

(71) Applicant: COMMISSARIAT À L'ÉNERGIE ATOMIQUE ET AUX ÉNERGIES ALTERNATIVES, Paris (FR)

(72) Inventor: Gabriele NAVARRO, GRENOBLE CEDEX (FR)

(21) Appl. No.: 17/544,138

(22) Filed: Dec. 7, 2021

(30) Foreign Application Priority Data
Dec. 7, 2020 (FR) 2012772

(51) Int. Cl. G11C 13/00; H01L 45/00

(52) U.S. Cl. CPC G11C 13/004; G11C 13/0038; G11C 13/0069; H01L 45/1608; G11C 2013/0078; H01L 45/1675; G11C 2013/0045; G11C 2213/72; H01L 45/1253

(57) ABSTRACT

A selector device intended to select a resistive memory cell includes a first selector device including a first active material and a second selector device including a second active material, the first selector device and the second selector device being connected in parallel.

### CROSS-REFERENCE TO RELATED APPLICATIONS

This application claims priority to French Patent Application No. 2012772, filed Dec. 7, 2020, the entire content of which is incorporated herein by reference in its entirety.

### FIELD

The technical field of the invention is that of resistive memories.

### BACKGROUND

For applications that require storage of information even when the voltage is switched off, non-volatile memories of EEPROM or FLASH type are conventionally used. These memories have however drawbacks such as long writing times, a density of memory dots limited by the size of the transistors used or instead a limited number of rewriting cycles.

The development of new technologies such as storage class memories (SCM) makes it possible to envisage a new generation of computers having improved performances and low energy consumption. Non-volatile resistive memories are very good candidates for the development of SCM technology and constitute a promising alternative to FLASH or EEPROM type memories.

Resistive memories are based on the use of an active medium of which the electrical resistance depends on the electric voltage applied to the terminals of the material. In other words a resistive memory cell has two states: an OFF state corresponding to a high resistance state and an ON state corresponding to a low resistance state. The active medium is inserted between two electrodes enabling the application of an electric voltage and ensuring the reading and the writing of the state of the resistive memory cell.

According to the type of active material used, different types of resistive memory may be produced: phase change materials (PCRAMs, also called PCMs or phase change memories), ion conducting materials (CBRAMs or conductive bridging memories), metal oxide materials (OxRAMs or oxide resistive memories), ferroelectric materials (FERAMs), magnetic memories (MRAMs), or magnetic memories with spin torque transfer (STTRAMs).

In order that resistive memories can compete with standard FLASH type memories, it is necessary to increase their scalability and their density. Scalability is linked to the dimension of the device: the reduction in the size of the device leads to a reduction in the current intensity required to programme the cell. Furthermore, the reduction in the size of the memory cell may also improve the density while leading to an increase in the number of devices for a same chip surface area.

To attain a density capable of rivalling other non-volatile memory technologies, it is necessary to carry out so-called 3D integration. This requires a modification of the architecture of the memory, notably with the replacement of the standard “transistor” type selector by a “diode” type selector integrated in series with the unitary memory cell. The structure is thus known as a “crossbar structure” and the unitary memory element is then constituted of a 1R resistive memory cell and a 1D or 1S for selector diode type selector, in series with the memory cell and arranged between an upper electrode and a lower electrode to form a 1D1R device. Each 1D1R device is located at the intersection between two metal lines (bit line and word line). A 1D1R device within the whole of the structure may be read/programmed with an opportune biasing of the bit lines and the word lines.

FIG. 1 illustrates the electric current supplied by a selector device as a function of the electric voltage applied to its terminals. The selector device has a first so-called “OFF” state in which it supplies a very low electric current. For applied voltages greater than a threshold, here between 492 mV and 495 mV, the selector device switches to a low resistance state, or “ON” state, in which it supplies a high current, so as to supply the device with which it is mounted in series.

FIG. 2 illustrates a 1D1R type device comprising a resistive memory cell connected in series to a diode type selector device. Even if diode type selectors have shown good reliability and can withstand a large number of activation cycles, necessary for operations of writing or reading of the state of the memory cell, these devices are not suited to the development of 3D integration. Indeed, diodes generally have a current in the “ON” state which may prove to be too low to program efficiently the resistive memory. More specifically, “backend” type diodes have very high and variable series resistances.

For this reason, several alternative solutions have been proposed. Those skilled in the art henceforth know different types of “backend” selector: field assisted ssuperlinear threshold (FAST), mixed ionic electronic conduction (MIEC) and notably ovonic threshold switches (OTS). These solutions are capable of delivering very high currents, but do not guarantee the reliability of the switch mechanism, because this mechanism intrinsically leads to a change in the structure of the material (i.e. change of phase, diffusion of an electrode, oxidation-reduction of an electrode, etc.), which produces a progressive deterioration of the device.

In a back end of line (BEOL) selector, two fundamental operations must be guaranteed:
the programming of the 1R memory in series:
the reading of the 1R memory in series.

The programming of the memory cell generally requires a current greater than or equal to 100 μA and comprises the “OFF-ON” switching (from the OFF state to the ON state) of the selector for each programming operation.

FIG. 3 illustrates the operation of reading a memory cell associated with a selector. A low electric current greater than or equal to 1 μA is sufficient to detect if the device is in its low resistance or SET state or instead in its high resistance or RESET state. Indeed, in a 1S1R “crossbar” system, the RESET state corresponds to a switching voltage of the system higher than that necessary if the system is in the SET state. The reading of the state of the memory cell is thus based on the following principle.

For reading, a low but sufficient electric current is required (>1 μA) to be able to detect if the memory device is quite simply in its SET or RESET state. In a 1D1R (1D for “diode”) or 1S1R (1S for “selector”) “crossbar” system, if the memory is in the “RESET” state (high resistance state), the overall switching voltage of the 1S1R system is higher than that in the case where the memory is in the “SET” state (low resistance state).

To read the state of the device, it thus suffices to apply a voltage noted V_{Reading} in FIG. 3. This voltage is comprised between the threshold voltage of the selector 1S and at best the sum of the threshold voltage of the 1S selector and that of the 1R memory in the RESET state (Vsw+Vth). If on applying the voltage V_{Reading} the measured current is low, the state of the device is the RESET state. If the measured current is high, the state of the device is the SET state.

It follows that during the reading operation, the 1S selector is subjected to a switching operation between its two states at least for each SET type reading. In a standard application, the number of programming operations of a memory device can vary from 10⁴ to 10¹² times. Conversely, the number of reading operations depends on the envisaged type of application. The frequency of reading operations may be comparable or even of orders of magnitude greater than that of programming operations.

The drawback of a backend selector is that each reading and programming operation leads to a deterioration of the device and reduces the lifetime thereof, while reducing the reliability of the memory cell.

To attain 3D integration of resistive memory cells, it is today necessary to improve the reliability and the lifetime of 1R1S type devices, comprising a resistive memory cell R and a selector device S ensuring the reading and the writing of the memory cell.

### SUMMARY

The present invention relates to a selector device intended to select a resistive memory cell. A second subject matter of the invention is a memory device integrating both a non-volatile memory function and a selector function. Another subject matter of the invention is a method for manufacturing the selector device according to the invention.

The invention offers a solution to the aforementioned problems, by proposing a selector device intended to select a resistive memory cell that comprises a first selector device comprising a first active material and a second selector device comprising a second active material, the first selector device and the second selector device being connected in parallel.

Resistive memory cell is taken to mean an electrical device having a first high resistance state or OFF state or instead RESET state and a second low resistance state or ON state or instead SET state. A resistive memory cell comprises a first electrode and a second electrode making it possible to apply an electric voltage to the terminals of an active material.

Active material is taken to mean a material of which the electrical resistance depends on the applied electric voltage. In other words, active material is taken to mean a material that can pass from a high resistance state to a low resistance state according to the voltage applied to its terminals.

The selector device according to an aspect of the invention comprises a first selector device and a second selector device, the first and second selector devices being connected in parallel, the first selector device being configured to supply an electric current suited to a reading of a state of the resistive memory cell and the second selector device being configured to supply an electric current suited to a writing of a state of the resistive memory cell. Connected in parallel is taken to mean an electrical connection such that the voltage applied to the terminals of the first selector device is the same as the voltage applied to the terminals of the second selector device.

Thanks to the invention, the use of a double selector device makes it possible to spread out the reading/writing cycles among the two selector devices connected in parallel, while increasing the lifetime and the reliability of the memory device. In other words, the second selector device will only be implemented during a writing or programming operation, limiting its deterioration. Beneficially, the use of the device according to the invention, comprising a selector device formed by the placing in parallel of a first and a second selector device, makes it possible to obtain a volatile memory device having great reliability, extended lifetime and reduced energy consumption.

The first active material has a first threshold voltage for the passage of an electric current and the second active material has a second threshold voltage for the passage of an electric current, the first threshold voltage being lower than the second threshold voltage. This makes it possible to apply a first threshold voltage to switch the first selector device into its low resistance state, without modifying the state of the second selector device. This condition is thus ideal for reading the state of the memory cell while using a low electric current and while limiting energy consumption. Furthermore, this condition avoids modifying the state of the second selector device, because the first electric voltage does not suffice to switch the second selector device into its active state. The second selector device is thus not deteriorated during a reading operation, while increasing the lifetime of the memory device.

The second selector device is used uniquely for the writing operation. In this case, it is necessary to apply the second threshold electric voltage to the selector device formed by the placing in parallel of the first and the second selector devices. In doing so, the use of the second selector device, capable of supplying the high electric current necessary to modify the state of the memory cell, is limited to the writing operation.

The invention enables the use of two selector devices having different properties. The first active material and the second active material are chosen so as to have a first selector device suited for the operation of reading the state of the memory cell and a second selector device suited for the operation of writing of the memory cell.

Beneficially, the selector device according to the invention may be used in all types of “crossbar” memories, which comprise the use of a selector, with different architectures such as 1S2R or 1S3R.

Apart from the characteristics that have been mentioned in the preceding paragraphs, the selector device according to an aspect of the invention may have one or more complementary characteristics among the following, considered individually or according to all technically possible combinations thereof:
the first active material has a first threshold voltage for the passage of an electric current and the second active material has a second threshold voltage for the passage of an electric current, the first threshold voltage being lower than the second threshold voltage;
the first selector device is a diode, for example made of polycrystalline silicon;
the second selector device is of OTS type or FAST type or MIEC type;
the second selector device is arranged to surround the first selector device;
the second selector device further comprises a first electrode of the second selector device and the first electrode of the second selector device and the second active material surround the first selector device;
the first electrode of the second selector device comprises a first and a second part of first electrode, the second active material comprises a first and a second part of active material, the first parts forming a first angle with the plane of the layers of the first selector device and the second parts forming a second angle with the plane of the layers of the first selector device;
the first parts are substantially normal to the plane of the layers of the first selector device and the second parts are substantially parallel to the plane of the layers of the first selector device.
the selector device is a backend type selector device.

Another subject matter of the invention is a memory device comprising the selector device according to the invention and a resistive memory cell, the selector device and the resistive memory cell being connected in series.

According to an embodiment, the memory cell is of phase change random access memory (PCRAM) or conductive bridge random access memory (CbRAM) or metal oxide random access memory (OxRAM) type.

According to an embodiment, the memory device according to the invention comprises a single memory cell.

According to another embodiment, the memory device according to the invention comprises two memory cells, each resistive memory cell being connected in series with the selector device.

According to an embodiment, the first selector device is a front end device and the second selector device is a back end device.

Another subject matter of the invention is a method for manufacturing a selector device intended to select a resistive memory cell characterised in that it comprises the following steps:
depositing a first set of layers comprising a first and a second electrode layer of a first selector device and a layer of a first active material of a first selector device;
depositing a second set of layers comprising a first electrode layer of a second selector device and a layer of a second active material of a second selector device;
electrically connecting the first electrode layer of the first set of layers and the first electrode layer of the second set of layers.
electrically connecting the second electrode layer of the first set of layers and the second electrode layer of the second set of layers.
   Beneficially, the manufacturing method according to the invention comprises the steps of:
depositing an electrically conductive layer intended to connect electrically the first electrode layer of the first set of layers and the first electrode layer of the second set of layers.
depositing a second electrode layer of the second selector device, the second electrode layer of the second set of layers being electrically connected to the second electrode layer of the first set of layers.

The deposition of the electrically conductive layer and the second electrode layer of the second selector device makes it possible to connect the two selector devices in parallel. According to an embodiment, the electrically conductive layer is an electrode layer of a resistive memory cell.

Beneficially, the method according to the invention makes it possible to obtain a selector device comprising a first and a second selector device. The connection of the two selector devices in parallel makes it possible, by choosing in an opportune manner the active material comprised in each of the two selectors, to extend the lifetime of the memory device as well as its reliability.

According to an embodiment, the method according to the invention further comprises a step of etching of the first set of layers.

According to an embodiment, step of deposition of the second set of layers further comprises the etching of the layers of the second set, the layers of the second set surrounding after etching the layers of the first set.

According to an embodiment, the method according to the invention further comprises a step of deposition and etching of a dielectric layer, the dielectric layer surrounding after etching the first set of layers.

According to an embodiment, the method according to the invention further comprises a step of deposition of a third set of layers comprising a resistive memory cell active material and a resistive memory cell electrode.

According to an embodiment, the step of deposition of the third set of layers is carried out so as to arrange the third set of layers in contact with the electrically conductive layer intended to connect an electrode layer of the first set of layers and the first electrode layer of the second set of layers.

According to this embodiment, the electrically conductive layer intended to connect an electrode layer of the first set of layers and the first electrode layer of the second set of layers also has the role of electrode layer for the resistive memory cell.

This embodiment makes it possible to connect in series the resistive memory cell and the parallel formed by the two selector devices.

According to an embodiment, the second electrode layer of the second selector device is a word line or a bit line.

Beneficially, the deposition and etching of the layers of the second set of layers makes it possible to produce a selector device comprising a first selector device and a second selector device in a compact and reproducible manner. In addition, the arrangement of the second selector surrounding the first selector makes it possible to produce efficiently a connection in parallel among the first and second selector device in an integrated device.

### BRIEF DESCRIPTION OF THE FIGURES

The figures are presented for indicative purposes and in no way limit the invention.

FIG. 1 represents an electric current applied voltage characteristic for a backend type selector;

FIG. 2 represents a memory device known to those skilled in the art comprising a resistive memory cell connected in series to a diode type selector:

FIG. 3 represents an electric current applied voltage characteristic for a 1S1R type memory device comprising a resistive memory cell and a selector device;

FIG. 4 schematically represents an embodiment of the memory device according to the invention comprising the selector device according to the invention;

FIG. 5 represents an embodiment of the selector device according to the invention;

FIG. 6 represents an electric current applied voltage characteristic for a polycrystalline silicon diode;

FIG. 7 represents an electric current applied voltage characteristic for an ovonic threshold switch or OTS;

FIG. 8 represents an electric current applied voltage characteristic for the memory device according to the invention;

FIGS. 9 and 9b schematically represent a sectional view of the memory device according to the invention;

FIG. 10 schematically represents the method for manufacturing a selector device according to the invention;

FIGS. 11a to 11f represent sectional views of the results obtained after each step of the manufacturing method according to the invention;

FIG. 12 illustrates another embodiment of a memory device according to the invention;

FIGS. 13 to 15 illustrate alternative embodiments of the memory device of FIG. 12:

FIGS. 16 to 18 illustrate other embodiments of memory devices according to the invention.

The invention and the different applications thereof will be better understood on reading the description that follows and by examining the figures that accompany it.

### DETAILED DESCRIPTION

Unless stated otherwise, a same element appearing in the different figures has a single reference.

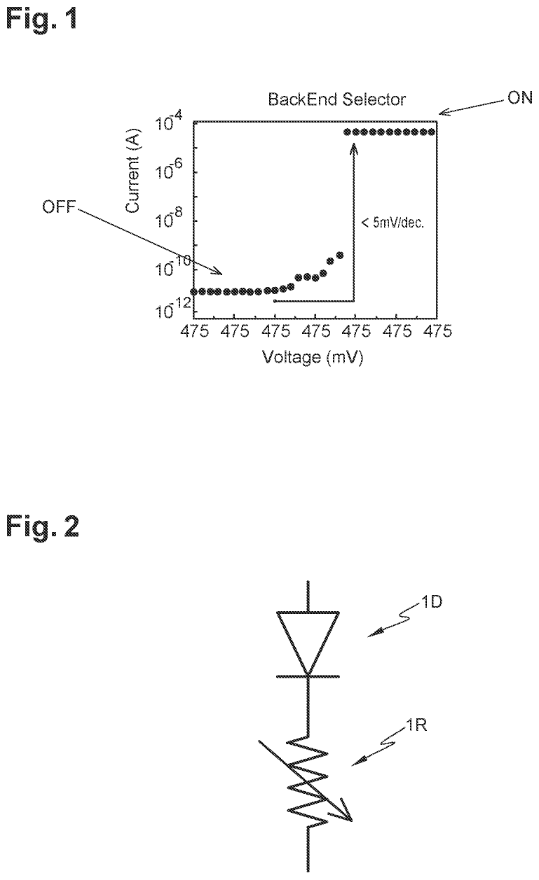

FIG. 1 has already been described with reference to the prior art.

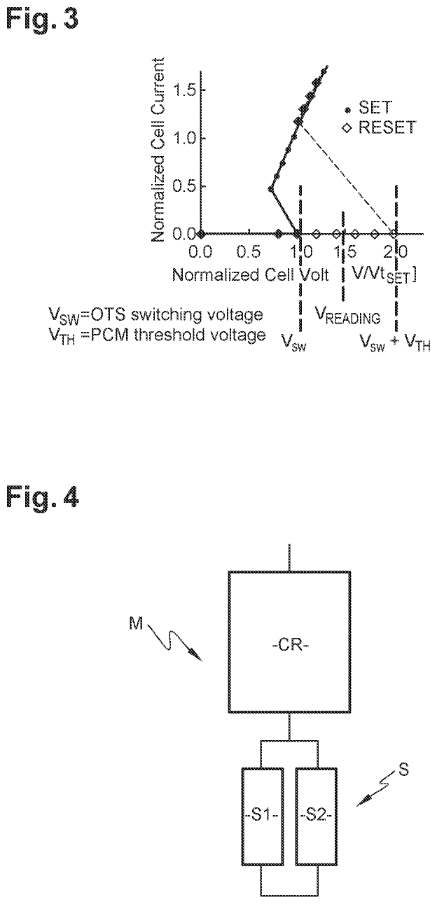

FIG. 2 has already been described with reference to the prior art.

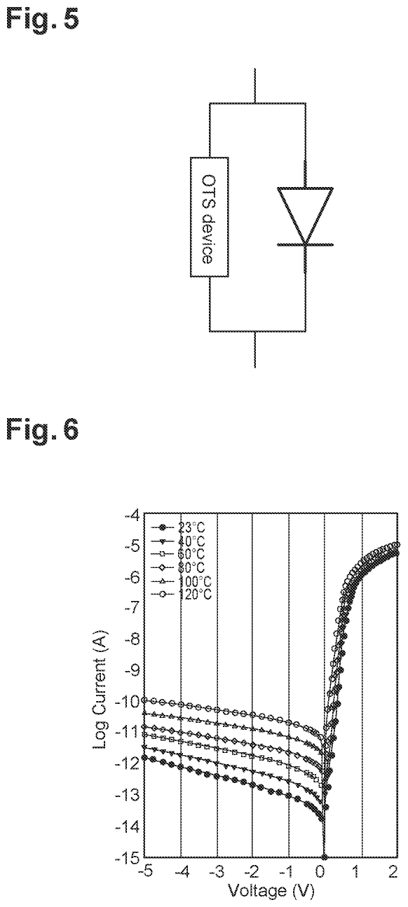

FIG. 3 has already been described with reference to the prior art.

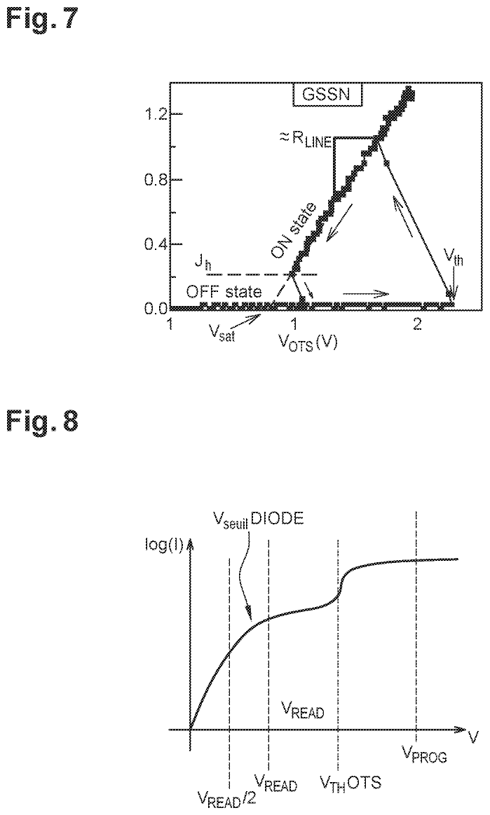

FIG. 4 schematically illustrates the memory device M according to an aspect of the invention, comprising a memory cell CR and a selector device S according to the invention, the memory cell and the selector device being connected in series. The selector device S according to the invention comprises a first selector device S1 and a second selector device S2. The first selector device S1 and the second selector device S2 are connected in parallel. Each of the two selector devices has two states, a first low resistance state and a second high resistance state. The electric current applied voltage characteristic of each selector device shows a threshold electric voltage above which the selector device switches into its low resistance state and supplies an electric current.

Beneficially, the first selector device and the second selector device are configured to have different threshold electric voltages. This is possible for example thanks to the choice of different active materials for the two devices.

The first selector device S1 comprises a first active material having a first threshold electric voltage. The second selector device S2 comprises a second active material having a second threshold electric voltage. The first selector device S1 supplies in its low resistance state an electric current lower than the second selector device S2.

Beneficially, thanks to the connection of the two selector devices S1 and S2 in parallel, it is possible to associate the operation of reading the state of the resistive memory cell CR with the first selector device and the operation of programming the state of the memory cell CR with the second selector device S2.

Indeed, the operation of reading the state of the resistive memory cell CR requires a low electric current, generally of the order of 1 μA. Thanks to the device according to the invention, it is thus possible to apply the first threshold voltage to the selector device S and to use the electric current supplied by the first selector device S1. This makes it possible to use uniquely the first selector device for the reading operation while avoiding activating the second selector device. The reading operation does not lead to any activation of the second selector device S2, while limiting its deterioration and while increasing the lifetime and the reliability of the device. In addition, by using a low electric current for the reading operation, the device according to the invention limits energy consumption.

Thus, to carry out an operation of writing of the resistive memory cell CR, it is possible to apply the second threshold electric voltage, which makes it possible to activate the second selector device S2, while placing it in its low resistance state. The second threshold electric voltage being higher than the first threshold electric voltage, the second selector device S2 supplies a very strong electric current, for example greater than or equal to 100 μA. This strong electric current may be opportunely used to modify the state of the resistive memory cell.

Beneficially, the activation of the second selector device S2 is carried out uniquely during a writing or programming operation. Writing operations being generally less frequent than simple reading operations, this makes it possible to reduce considerably degradation of the second selector device S2.

In other words, the resistive memory device according to the invention makes it possible to deal with the different constraints encountered during reading and writing operations, while increasing the reliability and the lifetime of the device and while limiting energy consumption.

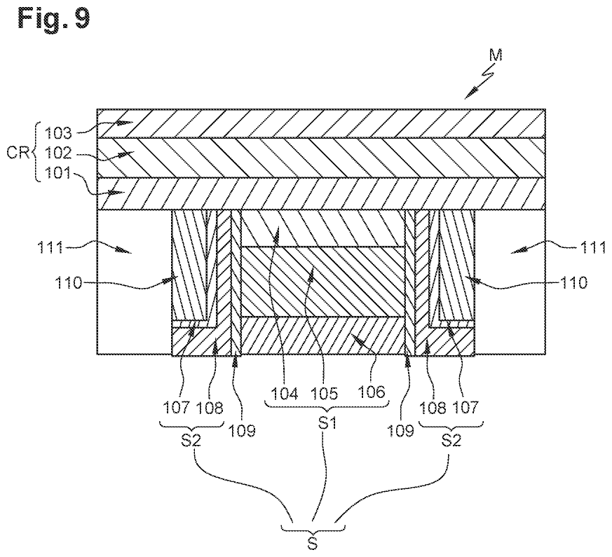

FIG. 5 shows a particular embodiment of the selector device S according to the invention. According to this embodiment, the first selector device S1 is a diode and the second selector device S2 is a backend selector device of ovonic threshold switch or OTS type.

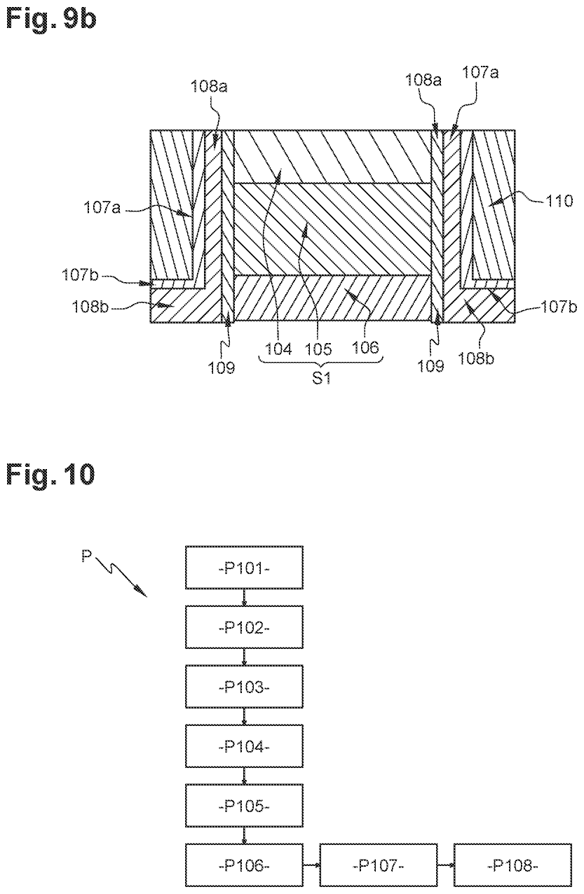

FIG. 6 illustrates the electrical characteristic of a backend diode with temperature. A threshold voltage around 1 V and currents around 10 μA for an applied voltage of 2V may be observed.

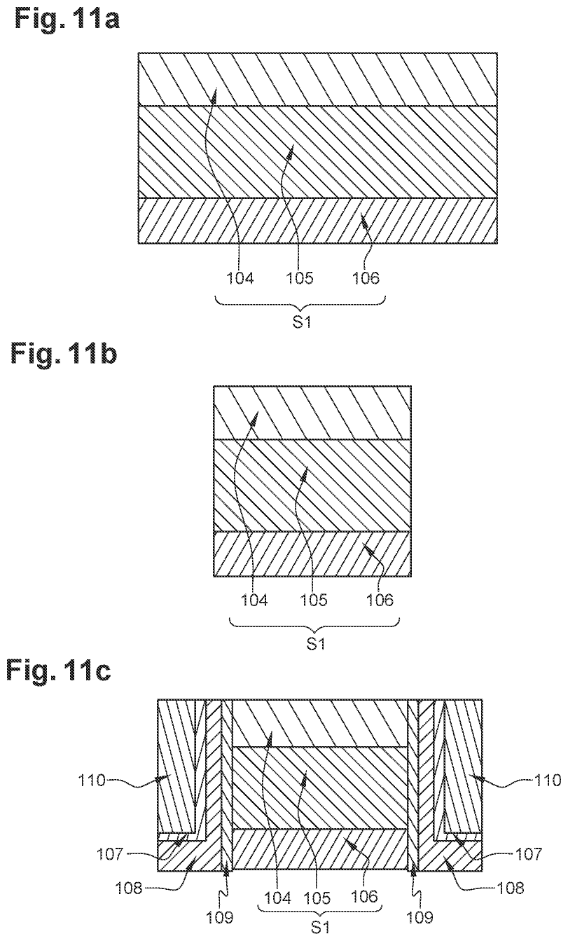

FIG. 7 illustrates the electrical characteristic of an OTS type backend selector. It may be seen that, for applied voltages greater than the threshold voltage V_{TH}, the OTS selector passes abruptly from the OFF state to the conductive ON state.

The choice of a diode for the first selector device comprises several benefits.

Firstly, the diode has very considerable non-linearity and it may be activated at relatively low voltages, with a first threshold voltage of the order of 1V.

Due to the low manufacturing temperature of the backend, normally less than 500° C., the resistance of the ON state or low resistance state of the diode may be highly variable. However, this is no longer a problem for the device according to the invention, where the active state of the diode is reserved solely for the reading operation and thus for a simple distinction between the ON state and the OFF state of the memory cell. Beneficially, the device according to the invention eliminates the necessity of mastering the current supplied by a diode during the writing operation.

Furthermore, the relatively high resistance of the diode in its ON state poses a strict limit to the miniaturisation of the diode, which is not relevant if the diode is used uniquely for reading operations.

In addition, the sub-threshold current of a diode is very low and compatible with very low leakage currents.

Beneficially, the device according to the invention uses the diode uniquely for a reading operation, the characteristics of the diode being perfectly suited for this operation, the diode may be of the p-n or p-i-n type, obtained by consecutive doping by ion implantation.

A p-n junction diode may comprise B doped polycrystalline silicon in the “p” zone of the diode and P doped polycrystalline silicon in the “n” zone of the diode.

A p-i-n junction diode may comprise B doped polycrystalline silicon in the “p” zone of the diode, intrinsic polycrystalline silicon in the “i” zone and P doped polycrystalline silicon in the “n” zone of the diode.

The choice of a backend type OTS selector for the second selector device S2 also comprises several benefits.

Firstly, the threshold voltage for this type of backend selector is high, for example greater than or equal to 1V. A correlation exists between leakage current I_{LEAK} and threshold voltage V_{TH}. Indeed, the higher the threshold voltage V_{TH}, the lower I_{LEAK}. Ideally, the sub-threshold leakage currents must be very low to reduce losses in memory cells outside of the selected memory device, at the intersection of the word line and the bit line. Beneficially, a high threshold voltage for the second selector device makes it possible to have greater selectivity of the memory point to address and thus a lower I_{LEAK}.

In addition, an OTS type selector in its active state can deliver a high current density, thus enabling programming of the resistive memory cell CR. This aspect is very favourable to scaling of the device.

The choice of an OTS type selector device is thus ideal for carrying out operations of programming or writing the resistive memory cell.

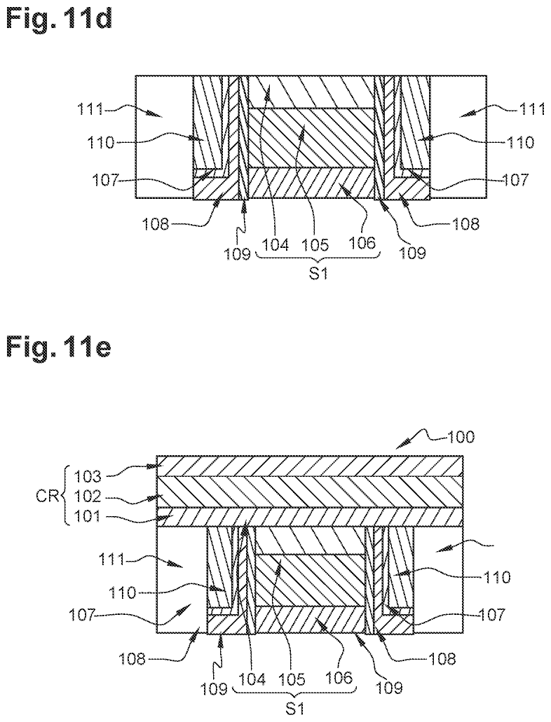

FIG. 8 illustrates the electrical characteristic of the device according to the invention illustrated in FIG. 5. The reading voltage V_{Read} must be higher than the threshold voltage of the diode V_{threshold,DIODE}, so as to place the diode in its active, or low resistance, state. At the voltage V_{Read} the selector device S2 remains in its high resistance state, the only electric current being that supplied by the diode. This configuration precisely makes it possible to read the state of the memory cell. If the memory is in a SET state or low resistance state with a resistance of the order of 10 kOhms, the electric current will be dominated by the resistance of the diode in series with that of the memory. One speaks of SET state of the 1S1R device. If on the other hand the memory is in a RESET state, with a resistance of the order of 1 MOhm, the electric current will be dominated by the resistance of the memory and thus be very low. In this case one speaks of SET state of the 1S1R device.

According to an embodiment, the device further comprises a comparator making it possible to distinguish between the two resistive states.

The programming operation will be carried out by applying the voltage V_{Prog} to the selector device. The voltage V_{Prog} is higher than the voltage V_{th,OTS} of the OTS type backend selector. The voltage V_{Prog} is higher than V_{read} and V_{threshold,Diode}. The voltage V_{Prog} is sufficiently high to change the state of the backend selector and to place it in its active state, which allows the selector to supply high currents. These currents are sufficiently high to enable programming of the resistive memory cell.

In a manner identical to a standard “crossbar” structure, voltage generators with a current control will have to be put in place to manage correctly the word line and the bit line of the addressed device, at the intersection of the two lines.

The technique of biasing a matrix formed by several memory devices according to the invention must take into account the presence of two different threshold voltages (thus a voltage for reading, a voltage for programming). The operation the most impacted by the presence of leakage currents is reading, which thus limits the maximum dimension of the matrix. Indeed, the reading operation is based on the distinction between a maximum current, associated with the SET state and a minimum current, associated with the RESET state. The current associated with the RESET state is impacted by the presence of all the devices on the same bit line and the same word line of the selected device V/2 biased fora “V/2” type matrix bias. This same current may also be impacted by all the V/3 biased devices of the matrix for a “V/3” type matrix bias.

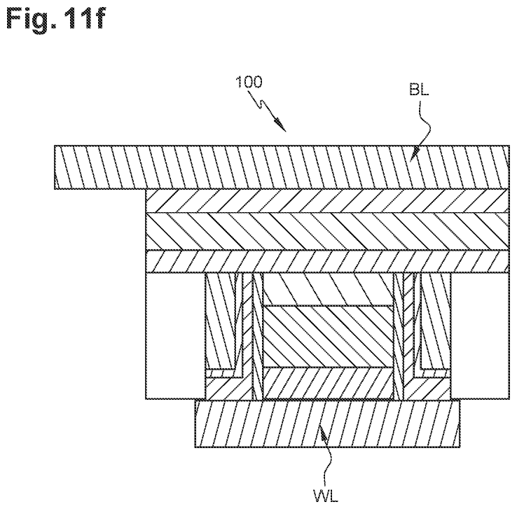

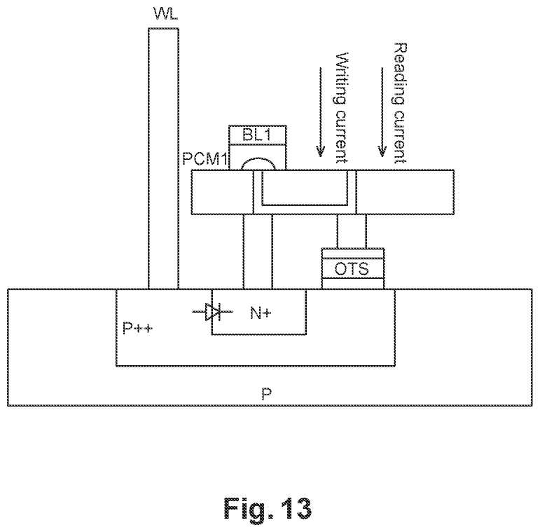

FIG. 9 illustrates an embodiment of the memory device M according to the invention, said device comprising:
A resistive memory cell CR comprising a first memory cell electrode 101, a second memory cell electrode 103 and a memory cell active material 102;
A first selector device S1 comprising a first electrode of the first selector device 104, a second electrode of the first selector device 106 and a first active material 105;
A second selector device S2 comprising a first electrode of the second selector device 107 and a second active material 108; the second electrode of the second selector device S2 is not represented in this figure and may be realised as illustrated by the conductive layer WL in FIG. 11f;
A dielectric layer 109 configured to electrically insulate the first selector device S1 and the second active material 108;
A second dielectric layer 110 configured to electrically insulate the first electrode of the second selector device 107 and a dielectric filling layer 111.

According to an embodiment, the first memory cell electrode 101 is arranged so as to connect electrically the first electrode of the first selector device 104 and the first electrode of the second selector device 107. This arrangement makes it possible to obtain a connection in series between the resistive memory cell CR and the selector device S comprising the first selector device S1 and the second selector device S2 which are in parallel (S1 and S2).

According to an embodiment, the device 100 further comprises an electrode or an electrically conductive element, which is not represented in FIG. 9, connecting the second electrode of the first selector device S2 and the second active material. According to an embodiment, this second electrode is a metal line of words or bits, as is illustrated in FIG. 11f. Beneficially, the electrically conductive element connecting the second electrode 106 of the first selector device S1 and the second active material 108 makes it possible to realise the connection in parallel of the first selector device S1 and the second selector device S2.

According to the embodiment illustrated in FIG. 9, the layers 109, 108, 107 and 110 are deposited and next intercalary layer or spacer etched. In other words, each layer is deposited and next etched along the direction normal to the plane of deposition of the layer itself. The etching may comprise the entire thickness of the layer, as in the case of the electrically insulating layer 109, which is configured as a vertical layer normal to the plane of deposition of the layers of the first selector device S1. Beneficially, the electrically insulating layer 109 makes it possible to electrically insulate the first selector device S1 and the second active material 108. Following the etching process, the insulating layer 109 surrounds the first selector device S1.

The etching of the layers 108 and 107 may be partial, only comprising a part of the thickness of the deposited layers. It follows that the layers 107 and 108 have a variable thickness along the direction normal to the plane of deposition of the layers of the first selector device S1. For example, the sectional view of FIG. 9 shows that the second active material 108 has an L-shaped section, with a foot of thickness e. Beneficially, the foot of thickness e of the layer forming the second active material 108 enables the connection in parallel between the first selector device S1 and the second selector device S2. This is possible thanks to the first electrode of the second selector device 107 and the metal element connecting the second electrode of the first selector 106 and the second active material 108, said metal element not being represented in FIG. 9. According to an embodiment illustrated in FIG. 11f, the metal element is a word line WL.

In other words, as is illustrated in FIG. 9b, the first electrode 107 of the second selector device comprises a first 107a and a second part 107b of first electrode, the second active material 108 comprises a first 108a and a second part 108b of active material 108, the first parts 107a, 108a forming a first angle with the plane of the layers 104, 105, 106 of the first selector device S1 and the second parts 107b, 108b forming a second angle with the plane of the layers 104, 105, 106 of the first selector device S1.

The embodiment illustrated in FIGS. 9 and 9b comprises first parts 107a and 108a normal to the plane of the layers of the first selector device S1 and second parts 107b and 108b parallel to the plane of the layers of the first selector device.

According to the embodiment represented in FIG. 9, the layers 107,108, 110 and 111 surround the first selector device S1. In other words, the layers 107 and 108 of the second selector device S2 surround the first selector device S1. This is possible thanks to the fact that the layers comprised in the second selector device S2 are at least partially spacer etched.

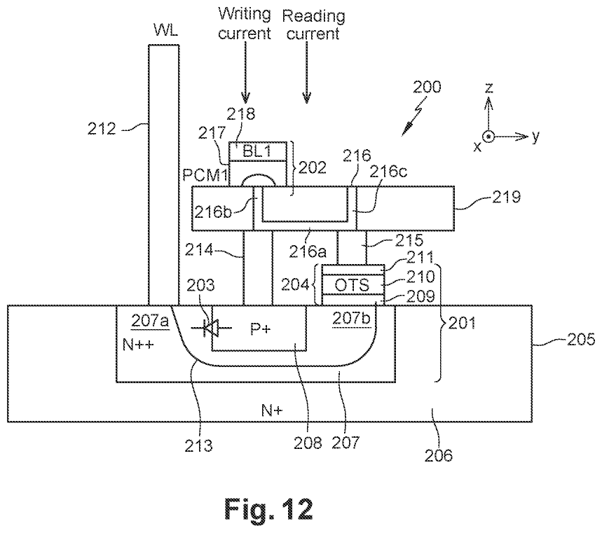

FIG. 10 schematically illustrates the steps of the method P for manufacturing a selector device according to the invention. The method according to the invention comprises a step P101 of depositing a first set of layers comprising a first selector device. According to an embodiment, the first selector device is a diode and the first set of layers comprises a first electrode of the first set of layers, a second electrode of the first set of layers and an active medium of the first set of layers, inserted among the two electrodes. According to an embodiment, the active medium comprises polycrystalline silicon.

The method according to the invention further comprises a step P102 of etching of the first set of layers. Following this etching step, the first set of layers may have a square, rectangular or circular section.

During step P103, a first dielectric layer or electrically insulating layer is deposited. According to an embodiment, step P103 further comprises the spacer or intercalary layer etching of the dielectric layer to electrically insulate the active medium of the first selector device and the active medium of the second selector device. Following the spacer etching step, the insulating layer surrounds the first selector device. In other words, the normal to the plane of the electrically insulating layer is oriented along a direction different from the normal to the plane of the layers of the first set of layers.

During step P104, a second set of layers is deposited. The second set of layers comprises a second active material of a second selector device and a first electrode of a second selector device. Step 104 may also comprise the spacer etching of the layers of the second set. According to an embodiment, before depositing the electrode layer, the layer comprising the second active material is partially etched, with a variable thickness as a function of the etching depth.

According to an embodiment, the variable thickness of the second active material forms a perimeter intended to host the first electrode of the second set of layers, as is illustrated in FIGS. 9 and 9b. In the same way, the first electrode of the second selector device is spacer etched, with a variable thickness as a function of the etching depth. According to an embodiment, the first electrode of the second selector device forms a perimeter intended to host a second insulating layer, as is illustrated in FIGS. 9 and 9b.

At the end of step P104, the first set of layers comprising the first selector device is surrounded by the second set of layers comprising an electrode layer and a layer of active material of the second selector device.

The method according to the invention further comprises a step P105 of depositing an electrically conductive layer intended to connect electrically the first electrode layer of the first set of layers and the first electrode layer of the second set of layers.

Beneficially, the electrically conductive layer deposited during step P105 makes it possible to realise the connection of the two selector devices in parallel. According to an embodiment, the electrically conductive layer deposited during step P105 is an electrode layer of a resistive memory cell, such as the layer 101 illustrated in FIG. 9.

The method according to the invention further comprises a step P106 of depositing a dielectric filling layer. According to an embodiment, step P106 further comprises the planarization of the dielectric filling layer. According to an embodiment, the dielectric filling surrounds the second selector device.

Step P107 comprises the deposition of a third set of layers comprising a memory cell electrode and a resistive memory cell active material. According to an embodiment, the third set of layers covers the electrically conductive layer deposited during step P105, so as to form a resistive memory cell. According to an embodiment, the resistive memory cell thus formed comprises the layers 101, 102 and 103 illustrated in FIG. 9.

In other words, the step of deposition of the third set of layers P107 is carried out so as to arrange the third set of layers in contact with the electrically conductive layer intended to connect an electrode layer of the first set of layers and the first electrode layer of the second set of layers.

According to this embodiment, the electrically conductive layer deposited during step 105 also has the function of electrode layer for the resistive memory cell, of which the structure is completed by the layers of the third set of layers.

Beneficially, step P107 makes it possible to realise the connection in series between the resistive memory cell and the parallel formed by the two selector devices.

According to an embodiment, step P107 comprises the etching of the third set of layers comprising the resistive memory cell.

The method according to the invention further comprises a step P108 of depositing a second electrode layer P108 of the second selector device, the second electrode layer of the second selector device being electrically connected to an electrode layer of the first selector device.

Beneficially, step P108 makes it possible to complete the connection in parallel of the two selector devices.

According to an embodiment, the second electrode layer of the second selector device is a word line or a bit line.

FIG. 11a schematically illustrates the result of step P101 when the first selector device S1 is a polysilicon diode. In this case, the first selector device S1 comprises a first electrode of the diode 101, a second electrode of the diode 103 and an active material comprising polycrystalline silicon 102. FIG. 11b shows the result of step P102, comprising the etching of the device S1 of FIG. 11a, resulting in a diode with square, rectangular or circular section.

FIG. 11c illustrates the second set of layers surrounding the first set of layers. The layers 107,108,109 and 110 have been described in relation with FIGS. 9 and 9b. Thanks to the steps of “spacer” etching, both the layer of second active material 108 and the electrode layer of the second set of layers 107 comprise a perimeter enabling the connection of the first and the second set of layers in parallel. In other words, the sectional view of FIG. 11c shows that the second active material 108 has an L-shaped section comprising a foot of thickness e. Beneficially, the L shape of the second active material 108 makes it possible to connect the first selector device S1 and the second selector device S2 in parallel.

FIG. 11d represents the result of step P103, with the deposition of a dielectric layer 111 surrounding the second set of layers.

FIG. 11e represents the result of step P107, with the deposition of the third set of layers comprising the resistive memory cell. The third set of layers comprises a memory cell electrode 101 also having the function of electrical connection between the first electrode 107 of the second selector device and the first electrode 104 of the first selector device. This arrangement makes it possible to realise the connection in parallel of the first and the second set of layers, corresponding to the first S1 and second S2 selector devices.

FIG. 11f represents the device according to the invention connected to a bit line BL and a word line WL, illustrating an embodiment of step P108. In particular, the word line WL makes it possible to complete the parallel connection between the first and the second selector device while having the function of second electrode of the second selector device.

Exemplary active materials used for the second selector device S2 according to the invention are: chalcogenide materials based on Ge, Se, As, Si, Te, Sb, N, C, etc. or sets of layers of several chalcogenide materials: Ge—Se, Ge—Se—Sb, As—Se—Ge—Si—N etc.

The electrodes may for example be made of TiN, TaN, W, TiWN, TiCN, TiSiN, C, etc. or sets of layers based on the same materials or other conductive materials.

The PCM materials used as active materials for the resistive memory cell CR are also materials based on chalcogenide alloys, or mixtures or sets of layers thereof: Ge—Sb—Te, Ga—Sb—Te, Ge—Te, Sb—Te, Ti—Sb—Te, Ti—Te.

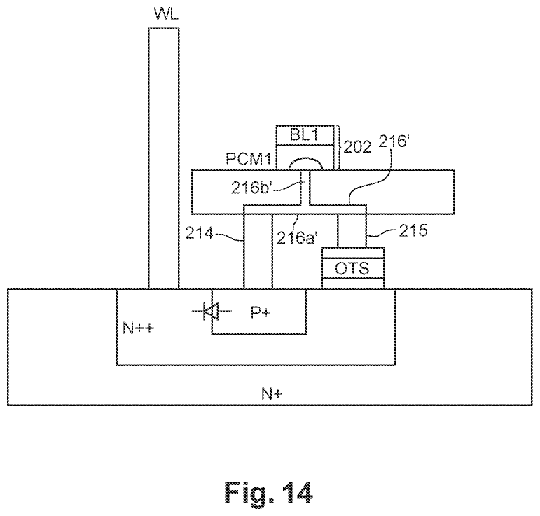

FIG. 12 illustrates another embodiment of a memory device 200 according to the invention comprising a selector device 201 according to the invention and a resistive memory cell 202 of PCM or PCRAM (phase change random access memory) type.

The selector device 201 according to the invention comprises a p-n junction diode 203 (here a P+-N++ junction diode) and an OTS type selector 204.

The particularity of this embodiment consists of a diode 203, front end embedded, for example in an SOI (silicon on insulator) substrate or in a silicon layer 205 doped in a suitable manner for the formation of the diode 203.

The silicon layer 205 comprises an N+ doped (i.e. strongly N doped) part 206 with a first N++ doped (i.e. very strongly N doped, that is to say doped more than the N+ doped part 206) inner well 207

A second P+ doped (i.e. strongly P doped) well 208 is formed inside the first N++ doped well 207. The two wells 207 and 208 thus enable the formation of the diode 203 comprising a P+/N++ junction. More specifically, the second P+ well 208 is substantially centred inside the first N++ well 207 and one of the parts 207a (here on the left in the drawing) of the first well 207 enables the formation of the P+/N++ junction at its interface with the second P++ well 208.

The upper part of the two wells 207 and 208 arrive on the surface of the silicon layer 206 in such a way as to be able to ensure back end contacts above the silicon layer 206.

The OTS selector 204 is thus back end formed on the part 207b (here on the right in the drawing) of the first well 207, the parts 207a and 207b being on either side of the second P+ well 208.

The OTS selector 204 comprises:

a first electrode 209 formed in contact with the upper surface of the part 207b of the first N++ well 207

an active layer 210 formed for example of a chalcogenide material deposited on the first electrode 209 and

a second electrode 211 formed on the active layer 201.

A word line (or WL) 212 is formed in contact with the upper surface of the part 207a of the first P+ well 208. This word line 212 may be considered as a first electrode of the diode 203 and is connected to the first electrode 209 of the OTS selector 204 via the N++ zone 207 (a conductive path 213 is represented in a purely schematic manner in order to illustrate this conductive link). The conductive path 213 is obviously slightly resistive (due to the N++ nature of the zone 207) but sufficient to ensure good conduction between the line 212 and the first electrode 209.

Two conductive electrodes 214 and 215, for example metal electrodes, are respectively arranged on the P+ well 208 of the diode 203 and on the second electrode 211 of the OTS selector 204. The electrode 214 may be considered as the second electrode of the diode 203.

A U-shaped electrode 216 comprising a U base 216a in the plane of the layers and two U-shaped arms (respectively 216b and 216c) are arranged such that the base of the U 201a is in contact respectively with the conductive electrodes 214 and 215. This U-shaped electrode, 216, is for example realised in the form of a liner deposited in a trench etched in an insulator zone, and extends along the direction x perpendicular to the sectional plane of FIG. 12.

The PCM memory 202 comprises an active layer 217 arranged above and in contact with the arm 216b of the U-shaped electrode 216. This active layer 217 is formed of a phase change material, typically a chalcogenide material.

A bit line BL1 218 is arranged above and in contact with the active layer 217.

According to this embodiment, the bit line 218 acts as upper electrode for the PCM memory 202 and the arm 216b of the U-shaped electrode 216 (and more generally the U-shaped electrode 216) acts as lower electrode for the PCM memory 202.

According to this embodiment, it is observed that the second electrode 214 of the diode 203 and the upper electrode 211 of the OTS selector 201 are electrically connected by the U-shaped electrode 216.

Thus, the first selector device formed by the diode 203 and the second selector device 204 formed by the OTS selector are connected in parallel. Further, the PCM memory cell 202 is in series with the two selectors 203 and 204 mounted in parallel.

The interest of such an embodiment notably lies at the technological level, in terms of manufacture, since it makes it possible to separate the manufacture of the first selector (the diode 203), front end produced, from the remainder of the device, back end produced with higher metallisation levels

It will furthermore be noted that, according to the invention, the diode is used only for reading such that its dimensions may be reduced because it does not need to allow an important current to pass (i.e. reading current of the PCM memory); the N++ zone 206 must be dimensioned to allow the writing current coming from the OTS selector 204 to pass.

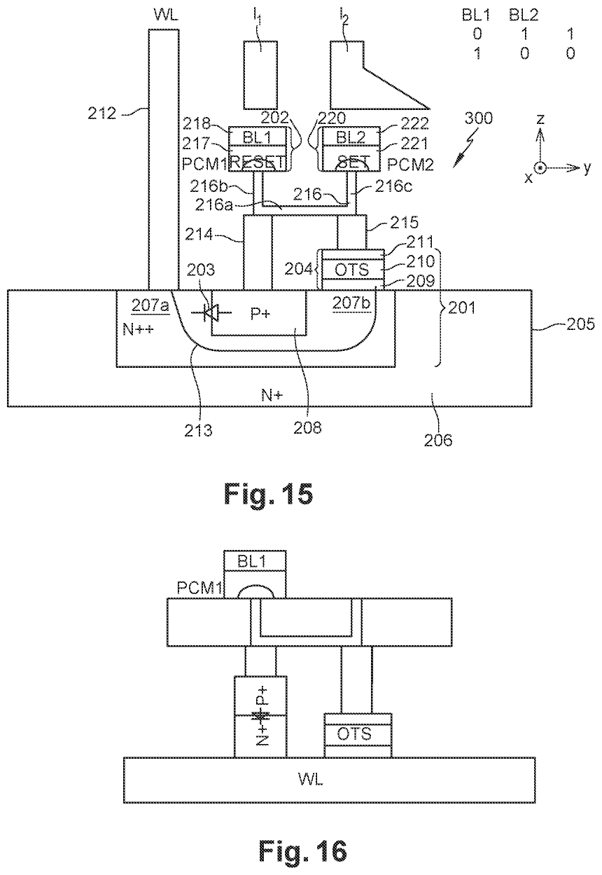

FIG. 13 illustrates another embodiment of a memory device according to the invention. This device is in all points comparable with that of FIG. 12 with the difference that the P and N dopings of the back end zone are inversed. Thus, the P+ well 208 becomes an N+ well and the N++ well 207 becomes a P++ well. More generally, it is possible to inverse the P and N dopings in the invention.

The N+ doped part 206 in which the wells are embedded becomes indifferently a P or P+ zone.

At the operating level of the memory device, the only change consists in the direction of the reading current which is reversed with respect to that of FIG. 12, the diode of FIG. 13 being conductive in an opposite direction with respect to its arrangement of FIG. 12.

FIG. 14 illustrates an alternative of the device 200 of FIG. 12. The only difference concerns the electrode 216. It is observed in fact that the arm 216c of the U-shaped electrode 216 has no usefulness in the device 200, if it is not that the formation of a U shape is easily achievable in the form of a liner. In the embodiment of FIG. 14, the U-shaped electrode 216 is replaced by an inversed T-shaped electrode 216′ comprising a base 216a′ in the plane of the layers and a perpendicular arm 216b′. As in FIG. 12, the base 216a′ is arranged such that it is in contact respectively with the conductive electrodes 214 and 215 whereas the arm 216b′ acts as lower electrode for the PCM memory 202. The active layer of the PCM memory is located above and in contact with the arm 216b′.

FIG. 15 illustrates an alternative 300 of the memory device of FIG. 12. The device 300 is identical to the device 200 of FIG. 12 (the common characteristics bear the same reference numbers) with the difference that it comprises in addition a second PCM memory cell 220 in addition to the first PCM memory cell 202.

The PCM memory cell 220 comprises an active layer 221 arranged above and in contact with the arm 216c of the U-shaped electrode 216. This active layer 221 is formed of a phase change material, typically a chalcogenide material.

A bit line BL1 222 is arranged above and in contact with the active layer 221.

According to this embodiment, the bit line 222 acts as upper electrode for the second PCM memory 220 and the arm 216c of the U-shaped electrode 216 (and more generally the U-shaped electrode 216) acts as lower electrode for the second PCM memory 220.

The benefit of the embodiment of FIG. 15 is to benefit from the existence of the other arm of the U-shaped electrode to add another PCM memory.

According to this embodiment, each of the two PCM memory cells 202 and 220 is mounted in series with the two selectors 203 and 204 in such a way as to form two 1T1R assemblies mounted in parallel.

In the presence of the two PCM memories, one of the principles of the invention may be to program one in the SET state and the other in the RESET state.

To do so, two different pulses 11 and 12 are applied to the respective upper electrodes 218 and 222 (i.e. the bit lines BL1 and BL2) of the memory cells 202 and 220.

As a reminder, a PCM memory cell uses a phase change material capable of switching very rapidly and reversibly between an amorphous phase and a crystalline phase. Yet these two phases have very great differences in properties. The amorphous phase is notably characterised by a high electrical resistivity, whereas the crystalline phase has a much lower electrical resistivity. Thus, the information bit is encoded by the difference in resistivity between the amorphous state and the crystalline state of the phase change material. Typically, the amorphous phase represents the logic level ‘0’ and the crystalline state represents the logic level ‘1’. The transition from the crystalline state to the amorphous state is obtained by applying a short pulse of high amplitude current, to locally melt the crystalline material and make it amorphous. The transition from the amorphous state to the crystalline state is also based on a heating up of the material, to a crystallisation temperature however less high. It is obtained by applying a current pulse that is longer but of smaller amplitude

In this instance, the pulse 11 applied to the cell 202 is going to make the active material of the cell 202 amorphous through heating. The same phenomenon is going to take place with the pulse 12 applied to the cell 220, the difference consisting in that the pulse 12 is longer than the pulse 11 and continues with a current ramp of less high intensity; thus, the end of the pulse 12 is going to make it possible to crystallise the active material of the cell 220. Thus, the first pulse 11 is going to place the cell 202 in a RESET (high resistance) state whereas the pulse 12 is going to place the cell 220 in a SET (low resistance) state. It will be noted that the writing of the cells 202 and 220 takes place through the passage of current in the OTS selector 201.

Reading for its part will take place via the selector formed by the diode 203. When the cell 202 is going to be “read”, a high resistance will be measured at its terminals and when the cell 220 is going to be “read”, a lower resistance will be measured at its terminals.

The device 300 of FIG. 15 is thus a double cell per bit or DLC (double level cell) type device which uses the knowledge of two states to reinforce the probability of knowing a single state.

According to this embodiment, the other arm of the electrode is thus used in a pragmatic manner. The two items of information are compared to have more certain information. It is even possible to have another resistive information between the bit lines 201 and 222 (BL1 and BL2).

Such a configuration is particularly useful for applications that depend in a critical manner on the retention of the information stored in the memory.

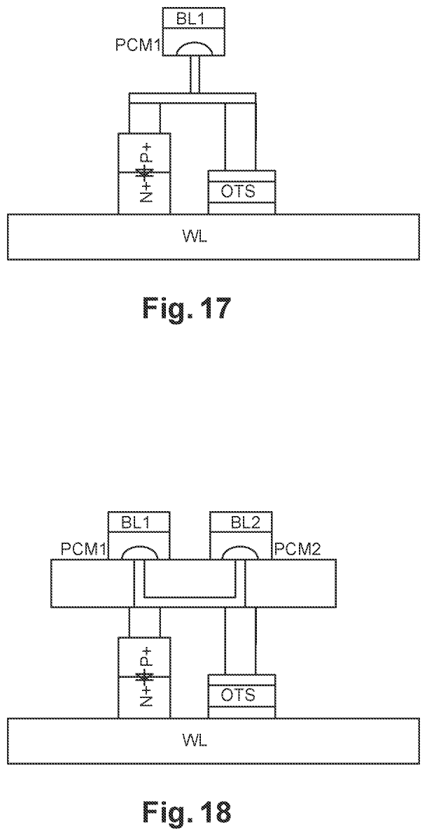

FIGS. 16 to 18 illustrate other embodiments of the invention in which the two selectors (diode and OTS) are directly formed at the same metal level above a word line.

The invention is particularly beneficial in the case where the first selector is a diode and the second selector is an OTS type selector.

Certain embodiments have been described in the case of a PCM type memory cell but the invention could also apply to other resistive memory cells such as OxRam or CBRAM.

1. A selector device configured to select a resistive memory cell, comprising a first selector device comprising a first active material and a second selector device comprising a second active material, the first selector device and the second selector device being connected in parallel, the first selector device being configured to supply an electric current adapted to a reading of a state of the resistive memory cell and the second selector device being configured to supply an electric current adapted to a writing of a state of a resistive memory cell

2. The selector device according to claim 1, wherein the first active material has a first threshold voltage for the passage of an electric current and the second active material has a second threshold voltage for the passage of an electric current, the first threshold voltage being lower than the second threshold voltage.

3. The selector device according to claim 1, wherein the first selector device is a diode.

4. The selector device according to claim 1, wherein the second selector device is an ovonic threshold switch or a field assisted superlinear threshold selector or a mixed ionic electronic conduction selector.

5. The selector device according to claim 1, wherein the second selector device arranged to surround the first selector device.

6. The selector device according to claim 1, wherein the second selector device further comprises a first electrode of the second selector device and wherein the first electrode of the second selector device and the second active material surround the first selector device.

7. The selector device according to claim 6, wherein the first electrode of the second selector device comprises a first and a second part of first electrode, the second active material comprises a first and a second part of active material, the first parts forming a first angle with a plane of the layers of the first selector device and the second parts forming a second angle with a plane of the layers of the first selector device.

8. The selector device according to claim 7, wherein the first parts are substantially normal to the plane of the layers of the first selector device and the second parts are substantially parallel to the plane of the layers of the first selector device.

9. A memory device comprising the selector device according to claim 1 and a resistive memory cell, the selector device and the resistive memory cell being connected in series.

10. The memory device according to claim 9, comprising a single memory cell.

11. The memory device according to claim 9, comprising two memory cells each resistive memory cell being connected in series with the selector device.

12. The memory device according to claim 9, wherein the first selector device is a front end device and the second selector device is a back end device.

13. A method for manufacturing a selector device configured to select a resistive memory cell, the method comprising:
depositing a first set of layers comprising a first and a second electrode layer of a first selector device and a layer of a first active material of the first selector device;
depositing a second set of layers comprising a first and a second electrode layer of a second selector device and a layer of a second active material of a second selector device;
electrically connecting the first electrode layer of the first set of layers and the first electrode layer of the second set of layers, and
electrically connecting the second electrode layer of the first set of layers and the second electrode layer of the second set of layers.

14. The method for manufacturing a selector device according to claim 13, further comprising:
depositing an electrically conductive layer configured to connect electrically the first electrode layer of the first set of layers and the first electrode layer of the second set of layers, and
depositing the second electrode layer of the second selector device, the second electrode layer of the second selector device being electrically connected to the second electrode layer of the first set of layers.

15. The method for manufacturing a selector device according to claim 13, further comprising etching the first set of layers.

16. The method for manufacturing a selector device according to the claim 15, wherein the deposition of the second set of layers further comprises etching the layers of the second set, the layers of the second set surrounding after etching the layers of the first set.

17. The method for manufacturing a selector device according to claim 15, further comprising depositing and etching a dielectric layer, the dielectric layer surrounding after etching the first set of layers.

18. The method for manufacturing a selector device according to claim 15, further comprising depositing a third set of layers comprising a resistive memory cell active material and a resistive memory cell electrode.

19. The method for manufacturing a selector device according to the claim 18, wherein the deposition of the third set of layers is carried out so as to arrange the third set of layers in contact with the electrically conductive layer intended to connect the first electrode layer of the first set of layers and the first electrode layer of the second set of layers.
